(19) United States
(12) Patent Application Publication
(10) Pub. No.: US 2020/0295143 A1
(43) Pub. Date: Sep. 17, 2020

(54) OXIDE SEMICONDUCTOR THIN FILM, THIN FILM TRANSISTOR, AND SPUTTERING TARGET

(71) Applicant: KABUSHIKI KAISHA KOBE SEIKO SHO (KOBE STEEL, LTD.), Hyogo (JP)

(72) Inventors: Yumi TERAMAE, Kobe-shi (JP); Hiroshi GOTO, Kobe-shi (JP); Mototaka OCHI, Kobe-shi (JP); Aya HINO, Kobe-shi (JP)

(73) Assignee: KABUSHIKI KAISHA KOBE SEIKO SHO (KOBE STEEL, LTD.), Hyogo (JP)

(21) Appl. No.: 16/759,544

(22) PCT Filed: Oct. 29, 2018
(86) PCT No.: PCT/JP2018/040204

§ 371 Date: Apr. 27, 2020

(30) Foreign Application Priority Data
Nov. 29, 2017 (JP) 2017-229663
Aug. 24, 2018 (JP) 2018-157571

(51) Int. Cl. H01L 29/24; H01L 29/786; H01L 21/02; C23C 14/08; C23C 14/34

(52) U.S. Cl. CPC H01L 29/24; H01L 29/7869; H01L 21/02631; C23C 14/3407; C23C 14/085; C23C 14/086; H01L 21/02565

(57) ABSTRACT

An object of the present invention is to provide: an oxide semiconductor thin film which is produced at relatively low cost and has a high carrier mobility and a high resistance to light stress when used for forming a thin film transistor; and a thin film transistor formed using the oxide semiconductor thin film. The oxide semiconductor thin film contains In, Zn, and Fe, wherein, with respect to a total number of In atoms, Zn atoms, and Fe atoms, a number of In atoms accounts for greater than or equal to 20 atm % and less than or equal to 89 atm %, a number of Zn atoms accounts for greater than or equal to 10 atm % and less than or equal to 79 atm %, and a number of Fe atoms accounts for greater than or equal to 0.2 atm % and less than or equal to 2 atm %. The present invention involves a thin film transistor including the oxide semiconductor thin film.

### TECHNICAL FIELD

The present invention relates to an oxide semiconductor thin film, a thin film transistor, and a sputtering target.

### BACKGROUND ART

A thin film transistor (TFT) formed using an amorphous oxide semiconductor has a higher carrier mobility than that formed using, for example, an amorphous silicon semiconductor. Furthermore, the amorphous oxide semiconductor has a wide optical bandgap and high visible light transmittance. Moreover, a thin film of the amorphous oxide semiconductor can be deposited at a lower temperature than that of the amorphous silicon semiconductor. It is anticipated that, utilizing these characteristics, the amorphous oxide semiconductor thin film will be applied to a next-generation large display which can be driven at a high speed at a high resolution and a flexible display formed using a resin substrate which requires deposition at low temperatures.

As such an amorphous oxide semiconductor thin film, an In—Ga—Zn—O (IGZO) amorphous oxide semiconductor thin film, which contains indium, gallium, zinc, and oxygen, is known (see Japanese Unexamined Patent Application, Publication No. 2010-219538, for example). A thin film transistor formed using the amorphous silicon semiconductor has a carrier mobility of approximately 0.5 cm²/Vs, whereas a TFT formed using the IGZO amorphous oxide semiconductor thin film disclosed in the above-described patent document has a mobility of greater than or equal to 1 cm²/Vs.

As an amorphous oxide semiconductor thin film having further improved mobility, an oxide semiconductor thin film containing indium, gallium, zinc, and tin (an In—Ga—Zn—Sn amorphous oxide semiconductor thin film) is known (see Japanese Unexamined Patent Application, Publication No. 2010-118407, for example). A TFT formed using the In—Ga—Zn—Sn amorphous oxide semiconductor thin film disclosed in the above-described patent document has a channel length of 1,000 μm and a carrier mobility of greater than 20 cm²/Vs. However, a TFT with a short channel length tends to have a lower carrier mobility; the carrier mobility in a low channel region may be insufficient, for example, for use in a next-generation large display, which is required to have high-speed performance.

Furthermore, since these amorphous oxide semiconductors contain gallium (Ga), which is a rare element, a production cost is relatively high. Therefore, there is a demand for an oxide semiconductor which does not contain Ga.

Moreover, for display applications of an amorphous oxide semiconductor thin film to be used for a thin film transistor, it is desired that a successive threshold voltage shift is small even when the thin film transistor is irradiated with light, i.e., that its resistance to light stress is high.

### PRIOR ART DOCUMENTS

### Patent Documents

Patent Document 1: Japanese Unexamined Patent Application, Publication No. 2010-219538

Patent Document 2: Japanese Unexamined Patent Application, Publication No. 2010-118407

### SUMMARY OF THE INVENTION

### Problems to be Solved by the Invention

The present invention was made in view of the foregoing circumstances, and an object of the present invention is to provide: an oxide semiconductor thin film which is produced at relatively low cost and has a high carrier mobility and a high resistance to light stress when used in forming a thin film transistor; a thin film transistor formed using the oxide semiconductor thin film; and a sputtering target for use in forming the oxide semiconductor thin film.

### Means for Solving the Problems

The present inventors have completed the present invention by finding that an oxide semiconductor thin film containing a predetermined amount of iron (Fe) has a high carrier mobility and a high resistance to light stress even without containing Ga.

More specifically, one aspect of the invention made for solving the aforementioned problems is an oxide semiconductor thin film containing In, Zn, and Fe, wherein, with respect to a total number of In atoms, Zn atoms, and Fe atoms, a number of In atoms accounts for greater than or equal to 20 atm % and less than or equal to 89 atm %, a number of Zn atoms accounts for greater than or equal to 10 atm % and less than or equal to 79 atm %, and a number of Fe atoms accounts for greater than or equal to 0.2 atm % and less than or equal to 2 atm %.

Since the number of In atoms and the number of Zn atoms fall within the above ranges and the number of Fe atoms accounts for greater than or equal to the lower limit, the oxide semiconductor thin film has a high resistance to light stress. Furthermore, since the number of Fe atoms in the oxide semiconductor thin film accounts for less than or equal to the upper limit, the carrier mobility of the thin film transistor formed using the oxide semiconductor thin film can be enhanced. Moreover, since the oxide semiconductor thin film does not need to contain Ga, production cost can be reduced.

It is preferred that, with respect to the total number of In atoms, Zn atoms, and Fe atoms in the oxide semiconductor thin film, the number of In atoms accounts for greater than or equal to 34 atm % and less than or equal to 80 atm %, the number of Zn atoms accounts for greater than or equal to 18 atm % and less than or equal to 65 atm %, and the number of Fe atoms accounts for greater than or equal to 0.2 atm % and less than or equal to 1.8 atm %. Since the number of In atoms and the number of Zn atoms fall within the above ranges and the number of Fe atoms accounts for greater than or equal to the lower limit, the oxide semiconductor thin film has a high resistance to light stress. Furthermore, since the number of Fe atoms in the oxide semiconductor thin film is less than or equal to the upper limit, the carrier mobility of the thin film transistor formed using the oxide semiconductor thin film can be further enhanced.

It is more preferred that, with respect to the total number of In atoms, Zn atoms, and Fe atoms in the oxide semiconductor thin film, the number of In atoms accounts for greater than or equal to 34 atm % and less than or equal to 60 atm %, the number of Zn atoms accounts for greater than or equal to 39 atm % and less than or equal to 65 atm %, and the number of Fe atoms accounts for greater than or equal to 0.2 atm % and less than or equal to 0.9 atm %. Since the number of In atoms and the number of Zn atoms fall within the above ranges and the number of Fe atoms accounts for greater than or equal to the lower limit, the oxide semiconductor thin film has a higher resistance to light stress. Furthermore, since the number of Fe atoms in the oxide semiconductor thin film is less than or equal to the upper limit, the carrier mobility of the thin film transistor formed using the oxide semiconductor thin film can be further enhanced.

According to another aspect of the invention, a thin film transistor includes the oxide semiconductor thin film of the one aspect of the invention. As it includes the oxide semiconductor thin film, the thin film transistor is produced at relatively low cost and has a high carrier mobility and a high resistance to light stress.

In the thin film transistor, a threshold voltage shift due to irradiation with light is preferably less than or equal to 2 V. By setting the threshold voltage shift to be less than or equal to the lower limit, performance stability of the thin film transistor can be improved.

The carrier mobility of the thin film transistor is preferably greater than or equal to 20 cm²/Vs. By setting the carrier mobility to be greater than or equal to the lower limit, the thin film transistor can be suitably used for, for example, a next-generation large display, which is required to have high-speed performance.

Still another aspect of the invention made for solving the above problems is a sputtering target for use in forming an oxide semiconductor thin film, the sputtering target containing In, Zn, and Fe, wherein, with respect to a total number of In atoms, Zn atoms, and Fe atoms, a number of In atoms accounts for greater than or equal to 20 atm % and less than or equal to 89 atm %, a number of Zn atoms accounts for greater than or equal to 10 atm % and less than or equal to 79 atm %, and a number of Fe atoms accounts for greater than or equal to 0.2 atm % and less than or equal to 2 atm %.

Since the number of In atoms, the number of Zn atoms, and the number of Fe atoms contained in the sputtering target fall within the above ranges, use of the sputtering target for depositing an oxide semiconductor thin film enables a thin film transistor having a high carrier mobility and a high resistance to light stress to be produced at relatively low production cost.

“Carrier mobility” as referred to herein means a field effect mobility of a thin film transistor in a saturation region, and “field effect mobility” as referred to herein means a value of μ_{FE} [m²/Vs] in a saturation region (V_{g}>V_{d}−Vₜₕ) of current-voltage characteristics of the thin film transistor, and is calculated by the following formula (1):

$${μ}_{PE} = \frac{\partial {I}_{d}}{\partial {V}_{g}} ( \frac{L}{{C}_{OX} \times W \times ( {V}_{g} - Vth )} ) , \qquad ( 1 )$$

wherein V_{g} [V] denotes a gate voltage, Vₜₕ [V] denotes a threshold voltage, I_{d} [A] denotes a drain current, L [m] denotes a channel length, W [m] denotes a channel width, and Cₒₓ [F] denotes a capacitance of a gate insulating film.

It is to be noted that “threshold voltage” of a thin film transistor as referred to herein means a gate voltage at which the drain current of the transistor is 10⁻⁹ A.

Furthermore, “threshold voltage shift due to irradiation with light” as referred to herein means an absolute value of a difference between threshold voltages before and after two-hour irradiation of a thin film transistor with a white LED at a substrate temperature of 60° C. under voltage conditions where a source-drain voltage and a gate-source voltage of the thin film transistor are 10 V and −10 V, respectively.

### Effects of the Invention

As described above, the thin film transistor formed using the oxide semiconductor thin film of the one aspect of the invention is produced at relatively low cost and has a high carrier mobility and a high resistance to light stress. Furthermore, by use of the sputtering target of the still another aspect of the invention, the oxide semiconductor thin film having a high carrier mobility and a high resistance to light stress can be formed at relatively low cost.

### BRIEF DESCRIPTION OF THE DRAWING

FIG. 1 is a schematic cross-sectional view illustrating a thin film transistor of an embodiment of the present invention, the thin film transistor being formed on a surface of a substrate.

### DESCRIPTION OF EMBODIMENTS

Hereinafter, embodiments of the present invention will be described in detail with appropriate reference to the drawing.

### Thin Film Transistor

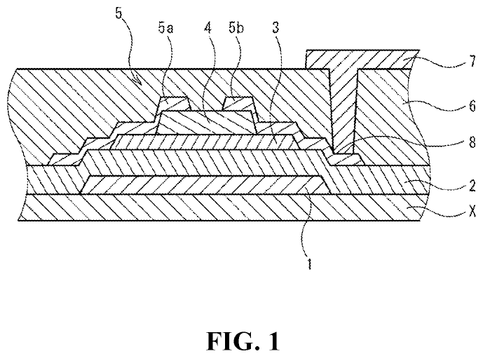

The thin film transistor illustrated in FIG. 1 can be used to produce, for example, display devices such as a next-generation large display, a flexible display, and the like. The thin film transistor is a bottom-gate transistor formed on a surface of a substrate X. The thin film transistor includes a gate electrode 1, a gate insulating film 2, an oxide semiconductor thin film 3, an etch stop layer (ESL) protective film 4, source and drain electrodes 5, a passivation insulating film 6, and a conductive film 7.

Substrate

The substrate X is not particularly limited, and can be, for example, a substrate used for a display device. The substrate X can be exemplified by transparent substrates such as a glass substrate, a silicone resin substrate, and the like. A glass used for the above glass substrate is not particularly limited, and examples include non-alkali glass, high strain point glass, soda-lime glass, and the like. Alternatively, a metal substrate such as a stainless-steel thin film, or a resin substrate such as a polyethylene terephthalate (PET) film can also be used as the substrate X.

In light of workability, an average thickness of the substrate X is preferably greater than or equal to 0.3 mm and less than or equal to 1.0 mm. Furthermore, a size and a shape of the substrate X are appropriately decided in accordance with a size and a shape of a display device or the like for which the substrate X is to be used.

Gate Electrode

The gate electrode 1 is formed on the surface of the substrate X and is conductive. A thin film forming the gate electrode 1 is not particularly limited, and an Al alloy and/or a stack in which a thin film of Mo, Cu, Ti, or the like or an alloy film is stacked on a surface of an Al alloy can be used.

A shape of the gate electrode 1 is not particularly limited, and is preferably, in light of controllability of a channel length and a channel width, a square or a rectangle in plan view, wherein a channel length direction and a channel width direction of the thin film transistor correspond to a horizontal direction and a vertical direction. The gate electrode 1 has such a size that the channel length and the channel width of the thin film transistor can be secured. The “channel length direction of the thin film transistor” as referred to herein means a direction in which a source electrode 5a and a drain electrode 5b of the thin film transistor face each other. Furthermore, the “channel width direction of the thin film transistor” as referred to herein means a direction that is orthogonal to the channel length direction of the thin film transistor and parallel to the surface of the substrate X.

The lower limit of an average thickness of the gate electrode 1 is preferably 50 nm, and more preferably 170 nm. Meanwhile, the upper limit of the average thickness of the gate electrode 1 is preferably 500 nm, and more preferably 400 nm. In a case in which the average thickness of the gate electrode 1 is less than the lower limit, the gate electrode 1 has a high resistance, which may increase power consumption at the gate electrode 1 and/or make disconnection likely to occur. Conversely, in a case in which the average thickness of the gate electrode 1 is greater than the upper limit, it may become difficult to planarize the gate insulating film 2 and the like to be stacked on a surface side of the gate electrode 1, which may degrade characteristics of the thin film transistor.

It is to be noted that, to improve coverage with the gate insulating film 2, a cross section in a thickness direction of the gate electrode 1 is preferably tapered so as to expand toward the substrate X. In the case of tapering the gate electrode 1, a taper angle is preferably greater than or equal to 30° and less than or equal to 40°.

Gate Insulating Film

The gate insulating film 2 is stacked on a surface side of the substrate X so as to cover the gate electrode 1. A thin film forming the gate insulating film 2 is not particularly limited, and can be a silicon oxide film; a silicon nitride film; a silicon oxynitride film; a metal oxide film of Al₂O₃, Y₂O₃, or the like; or the like. Furthermore, the gate insulating film 2 may have a single-layer structure of one of these thin films or a multilayer structure in which greater than or equal to two kinds of thin films are stacked.

A shape of the gate insulating film 2 is not limited as long as the gate electrode 1 is covered therewith; for example, the gate insulating film 2 may cover an entire surface of the substrate X.

The lower limit of an average thickness of the gate insulating film 2 is preferably 50 nm, and more preferably 100 nm. Furthermore, the upper limit of the average thickness of the gate insulating film 2 is preferably 300 nm, and more preferably 250 nm. In a case in which the average thickness of the gate insulating film 2 is less than the lower limit, the gate insulating film 2 may lack withstand voltage, which may result in breakdown of the gate insulating film 2 when a gate voltage is applied. Conversely, in a case in which the average thickness of the gate insulating film 2 is greater than the upper limit, a capacitor formed between the gate electrode 1 and the oxide semiconductor thin film 3 may lack capacitance, which may lead to an insufficient drain current. It is to be noted that when the gate insulating film 2 has a multilayer structure, “average thickness of the gate insulating film” means an average of a total thickness.

Oxide Semiconductor Thin Film

The oxide semiconductor thin film 3 is itself another embodiment of the present invention. The oxide semiconductor thin film 3 contains In, Zn, and Fe. The oxide semiconductor thin film 3 contains inevitable impurities as metal elements other than In, Zn, and Fe. In other words, the oxide semiconductor thin film 3 contains substantially no metal element other than In, Zn, and Fe.

The lower limit of a number of In atoms with respect to a total number of In atoms, Zn atoms, and Fe atoms accounts for 20 atm %, preferably 29 atm %, and more preferably 34 atm %. Meanwhile, the upper limit of the number of In atoms accounts for 89 atm %, preferably 81 atm %, more preferably 80 atm %, and still more preferably 60 atm %. In a case in which the number of In atoms accounts for less than the lower limit, a carrier mobility of the thin film transistor may decrease. Conversely, in a case in which the number of In atoms accounts for greater than the upper limit, leakage current of the oxide semiconductor thin film 3 may increase or a threshold voltage may shift to a negative side, which may turn the oxide semiconductor thin film 3 into a conductor.

The lower limit of a number of Zn atoms with respect to the total number of In atoms, Zn atoms, and Fe atoms accounts for 10 atm %, preferably 18 atm %, and more preferably 39 atm %. Meanwhile, the upper limit of the number of Zn atoms accounts for 79 atm %, preferably 70 atm %, and more preferably 65 atm %. When the number of Zn atoms accounts for less than the lower limit, the numbers of the other metal atoms relatively increase, which may turn the oxide semiconductor thin film 3 into a conductor. Conversely, in a case in which the number of Zn atoms accounts for greater than the upper limit, a carrier concentration may be suppressed, which may decrease the carrier mobility of the thin film transistor.

The lower limit of a number of Fe atoms with respect to the total number of In atoms, Zn atoms, and Fe atoms accounts for 0.2 atm %, preferably 0.4 atm %, and more preferably 0.5 atm %. Meanwhile, the upper limit of the number of Fe atoms accounts for 2 atm %, preferably 1.8 atm %, more preferably 1 atm %, and still more preferably 0.9 atm %. In a case in which the number of Fe atoms accounts for less than the lower limit, a threshold voltage shift due to irradiation with light may increase. Conversely, in a case in which the number of Fe atoms accounts for greater than the upper limit, the carrier concentration may be suppressed, which may decrease the carrier mobility of the thin film transistor.

It is preferred that, with respect to the total number of In atoms, Zn atoms, and Fe atoms in the oxide semiconductor thin film 3, the number of In atoms accounts for greater than or equal to 34 atm % and less than or equal to 81 atm %, the number of Zn atoms accounts for greater than or equal to 18 atm % and less than or equal to 65 atm %, and the number of Fe atoms accounts for greater than or equal to 0.2 atm % and less than or equal to 1.8 atm %. Since the number of In atoms and the number of Zn atoms fall within the above ranges and the number of Fe atoms accounts for greater than or equal to the lower limit, the oxide semiconductor thin film 3 has a high resistance to light stress. Furthermore, since the number of Fe atoms in the oxide semiconductor thin film 3 accounts for less than or equal to the upper limit, the carrier mobility of the thin film transistor formed using the oxide semiconductor thin film 3 can be further increased.

It is preferred that, with respect to the total number of In atoms, Zn atoms, and Fe atoms in the oxide semiconductor thin film 3, the number of In atoms accounts for greater than or equal to 34 atm % and less than or equal to 80 atm %, the number of Zn atoms accounts for greater than or equal to 18 atm % and less than or equal to 65 atm %, and the number of Fe atoms accounts for greater than or equal to 0.4 atm % and less than or equal to 1.8 atm %. Since the number of In atoms and the number of Zn atoms fall within the above ranges and the number of Fe atoms accounts for greater than or equal to the lower limit, the oxide semiconductor thin film 3 has a high resistance to light stress. Furthermore, since the number of Fe atoms in the oxide semiconductor thin film 3 accounts for less than or equal to the upper limit, the carrier mobility of the thin film transistor formed using the oxide semiconductor thin film 3 can be further increased.

It is more preferred that, with respect to the total number of In atoms, Zn atoms, and Fe atoms in the oxide semiconductor thin film 3, the number of In atoms accounts for greater than or equal to 34 atm % and less than or equal to 60 atm %, the number of Zn atoms accounts for greater than or equal to 39 atm % and less than or equal to 65 atm %, and the number of Fe atoms accounts for greater than or equal to 0.2 atm % and less than or equal to 1 atm %. Since the number of In atoms and the number of Zn atoms fall within the above ranges and the number of Fe atoms accounts for greater than or equal to the lower limit, the oxide semiconductor thin film 3 has a higher resistance to light stress. Furthermore, since the number of Fe atoms in the oxide semiconductor thin film 3 accounts for less than or equal to the upper limit, the carrier mobility of the thin film transistor formed using the oxide semiconductor thin film 3 can be further increased.

It is more preferred that, with respect to the total number of In atoms, Zn atoms, and Fe atoms in the oxide semiconductor thin film 3, the number of In atoms accounts for greater than or equal to 34 atm % and less than or equal to 60 atm %, the number of Zn atoms accounts for greater than or equal to 39 atm % and less than or equal to 65 atm %, and the number of Fe atoms accounts for greater than or equal to 0.5 atm % and less than or equal to 0.9 atm %. Since the number of In atoms and the number of Zn atoms fall within the above ranges and the number of Fe atoms accounts for greater than or equal to the lower limit, the oxide semiconductor thin film 3 has a higher resistance to light stress. Furthermore, since the number of Fe atoms in the oxide semiconductor thin film 3 accounts for less than or equal to the upper limit, the carrier mobility of the thin film transistor formed using the oxide semiconductor thin film 3 can be further increased.

A shape in plan view of the oxide semiconductor thin film 3 is not particularly limited, and in light of controllability of the channel length and the channel width of the thin film transistor, is preferably a shape similar to that of the gate electrode 1. The oxide semiconductor thin film 3 has such a size in plan view that the channel length and the channel width of the thin film transistor can be secured.

Furthermore, the size in plan view of the oxide semiconductor thin film 3 is preferably smaller than the size in plan view of the gate electrode 1 so that the oxide semiconductor thin film 3 can be surely provided directly over the gate electrode 1. The lower limit of a difference between lengths of sides in the channel length direction and the channel width direction of the oxide semiconductor thin film 3 and of the gate electrode 1 is preferably 2 nm, and more preferably 4 nm. Meanwhile, the upper limit of the difference between the lengths of the sides is preferably 10 nm, and more preferably 8 nm. In a case in which the difference between the lengths of the sides is less than the lower limit, part of the oxide semiconductor thin film 3 may fail to be provided directly over the gate electrode 1 owing to misalignment of patterning or the like; as a result, planarity of the oxide semiconductor thin film 3 may become poor and the characteristics of the thin film transistor may be degraded. Conversely, in a case in which the difference between the lengths of the sides is greater than the upper limit, the thin film transistor may unduly increase in size.

An average thickness of the oxide semiconductor thin film 3 can be decided in accordance with conditions under which the drain current can be turned off when the thin film transistor is used as a switching element. Specifically, it is preferred that an inside of the oxide semiconductor thin film 3 is completely depleted by applying a gate voltage. For this purpose, an average thickness t_{ch} [m] of the oxide semiconductor thin film 3 preferably satisfies a relation with respect to a carrier concentration N_{C} [m⁻³] shown in the following inequality (2):

N_{C}<4ϵ_{OX}ϵ_{AOS}ϕ_{f}/(qt_{ch}²) (2),

wherein ϵ_{OX} denotes a permittivity of an insulating film, ϵ_{AOS} denotes a permittivity of a semiconductor, ϕ_{f} [eV] denotes a Fermi level of the semiconductor, and q [C] denotes an electron charge. In light of a relation between the above inequality (2) and a carrier concentration described later, and of control accuracy of a thickness distribution in production of the oxide semiconductor thin film 3, the average thickness of the oxide semiconductor thin film 3 can be, for example, greater than or equal to 20 nm and less than or equal to 60 nm.

It is to be noted that to improve coverage with the source and drain electrodes 5, a cross section in a thickness direction of the oxide semiconductor thin film 3 is preferably tapered so as to expand toward the substrate X. In the case of tapering the oxide semiconductor thin film 3, a taper angle is preferably greater than or equal to 30° and less than or equal to 40 °.

The lower limit of the carrier concentration of the oxide semiconductor thin film 3 is preferably 1×10¹² cm⁻³, more preferably 1×10¹³ cm⁻³, and still more preferably 1×10¹⁴ cm⁻³. Meanwhile, the upper limit of the carrier concentration of the oxide semiconductor thin film 3 is preferably 1×10²⁰ cm⁻³, more preferably 1×10¹⁹ cm⁻³, and still more preferably 1×10¹⁸ cm⁻³. In a case in which the carrier concentration of the oxide semiconductor thin film 3 is less than the lower limit, the thin film transistor may lack drain current. Conversely, in a case in which the carrier concentration of the oxide semiconductor thin film 3 is greater than the upper limit, it may be difficult to completely deplete the inside of the oxide semiconductor thin film 3, which may result in the threshold voltage shifting to the negative side and the thin film transistor not functioning as a switching element.

The lower limit of a hole mobility of the oxide semiconductor thin film 3 is preferably 20 cm²/Vs, more preferably 23 cm²/Vs, and still more preferably 30 cm²/Vs. In a case in which the hole mobility of the oxide semiconductor thin film 3 is less than the lower limit, switching characteristics of the thin film transistor may be degraded. Meanwhile, the upper limit of the hole mobility of the oxide semiconductor thin film 3 is not particularly limited; in general, the hole mobility of the oxide semiconductor thin film 3 is less than or equal to 100 cm²/Vs. “Hole mobility” as referred to herein means a carrier mobility obtained by a Hall effect measurement.

ESL Protective Film

The ESL protective film 4 is a protective film which inhibits degradation of the characteristics of the thin film transistor due to damage on the oxide semiconductor thin film 3 at a time of forming the source and drain electrodes 5 by etching. A thin film forming the ESL protective film 4 is not particularly limited, and a silicon oxide film can be suitably used.

The lower limit of an average thickness of the ESL protective film 4 is preferably 50 nm, and more preferably 80 nm. Meanwhile, the upper limit of the average thickness of the ESL protective film 4 is preferably 250 nm, and more preferably 200 nm. In a case in which the average thickness of the ESL protective film 4 is less than the lower limit, the ESL protective film 4 may lack an effect of protecting the oxide semiconductor thin film 3. Conversely, in a case in which the average thickness of the ESL protective film 4 is greater than the upper limit, it may become difficult to planarize the passivation insulating film 6, and/or wiring extending from the source and drain electrodes 5 may become likely to disconnect.

Source and Drain Electrodes

The source and drain electrodes 5 cover part of the gate insulating film 2 and part of the ESL protective film 4, and are electrically connected to the oxide semiconductor thin film 3 at both ends of the channel of the thin film transistor. The drain current of the thin film transistor flows between the source electrode 5a and the drain electrode 5b in accordance with a voltage between the gate electrode 1 and the source electrode 5a and a voltage between the source electrode 5a and the drain electrode 5b.

A thin film forming the source and drain electrodes 5 is not particularly limited as long as it is conductive; for example, a thin film similar to that forming the gate electrode 1 can be used.

The lower limit of an average thickness of the source and drain electrodes 5 is preferably 100 nm, and more preferably 150 nm. Meanwhile, the upper limit of the average thickness of the source and drain electrodes 5 is preferably 400 nm, and more preferably 300 nm. In a case in which the average thickness of the source and drain electrodes 5 is less than the lower limit, the source and drain electrodes 5 may have a high resistance, which may increase power consumption at the source and drain electrodes 5, and/or may make disconnection likely to occur. Conversely, in a case in which the average thickness of the source and drain electrodes 5 is greater than the upper limit, it may become difficult to planarize the passivation insulating film 6, which may make it difficult to provide the conductive film 7 as wiring.

The lower limit of a distance between the source electrode 5a and the drain electrode 5b, which face each other, i.e., the channel length of the thin film transistor, is preferably 5 μm, and more preferably 10 μm. Meanwhile, the upper limit of the channel length of the thin film transistor is preferably 50 μm, and more preferably 30 μm. In a case in which the channel length of the thin film transistor is less than the lower limit, high-accuracy working may be needed, which may decrease production yield. Conversely, in a case in which the channel length of the thin film transistor is greater than the upper limit, a switching time period of the thin film transistor may be increased.

The lower limit of a length in the channel width direction of the source electrode 5a and the drain electrode 5b, i.e., the channel width of the thin film transistor, is preferably 100 μm, and more preferably 150 μm. Meanwhile, the upper limit of the channel width of the thin film transistor is preferably 300 μm, and more preferably 250 μm. In a case in which the channel width of the thin film transistor is less than the lower limit, the thin film transistor may lack drain current. Conversely, in a case in which the channel width of the thin film transistor is greater than the upper limit, the drain current may become excessive, which may unduly increase power consumption of the thin film transistor.

Passivation Insulating Film

The passivation insulating film 6 covers the gate electrode 1, the gate insulating film 2, the oxide semiconductor thin film 3, the ESL protective film 4, the source electrode 5a, and the drain electrode 5b, and prevents deterioration of the characteristics of the thin film transistor. A thin film forming the passivation insulating film 6 is not particularly limited, and a silicon nitride film, whose sheet resistance can be relatively easily controlled by hydrogen content, can be suitably used. Furthermore, to further increase controllability of the sheet resistance, the passivation insulating film 6 may have a two-layer structure of a silicon oxide film and a silicon nitride film, for example.

The lower limit of an average thickness of the passivation insulating film 6 is preferably 100 nm, and more preferably 250 nm. Meanwhile, the upper limit of the average thickness of the passivation insulating film 6 is preferably 500 nm, and more preferably 300 nm. In a case in which the average thickness of the passivation insulating film 6 is less than the lower limit, an effect of preventing the deterioration of the characteristics of the thin film transistor may be insufficient. Conversely, in a case in which the average thickness of the passivation insulating film 6 is greater than the upper limit, the passivation insulating film 6 may become unduly thick, which may cause a rise in the production cost of the thin film transistor or a drop in the production efficiency. It is to be noted that when the passivation insulating film 6 has a multilayer structure, “average thickness of the passivation insulating film” means an average of the total thickness.

Furthermore, a contact hole 8 is formed in the passivation insulating film 6 so that an electrical connection to the drain electrode 5b can be obtained. A shape and a size in plan view of the contact hole 8 is not particularly limited as long as the electrical connection to the drain electrode 5b is secured; for example, the shape can be a square/rectangle with each side being greater than or equal to 10 μm and less than or equal to 30 μm in plan view.

Conductive Film

The conductive film 7 is connected to the drain electrode 5b through the contact hole 8 formed in the passivation insulating film 6. The conductive film 7 forms wiring through which the drain current of the thin film transistor is acquired.

The conductive film 7 is not particularly limited, and a thin film similar to that forming the gate electrode 1 can be used. In particular, a transparent conductive film, which is suitable for display applications, is preferred. The transparent conductive film can be exemplified by an ITO film, a ZnO film, and the like.

A position at which the conductive film 7 is connected to the drain electrode 5b is preferably a position at which the drain electrode 5b is in contact with the gate insulating film 2 and which is not directly over the gate electrode 1. By connecting the conductive film 7 to the drain electrode 5b at such a position, planarity of a connection portion between the conductive film 7 and the drain electrode 5b is increased, whereby an increase in contact resistance can be inhibited.

The lower limit of an average wiring width of the conductive film 7 is preferably 5 μm, and more preferably 10 μm. Meanwhile, the upper limit of the average wiring width of the conductive film 7 is preferably 50 μm, and more preferably 30 μm. In a case in which the average wiring width of the conductive film 7 is less than the lower limit, the wiring formed of the conductive film 7 may have a high resistance, which may increase the power consumption and/or a voltage drop at the wiring formed of the conductive film 7. Conversely, in a case in which the average wiring width of the conductive film 7 is greater than the upper limit, a degree of integration of the thin film transistor may decrease. “Average wiring width of the conductive film” as referred to herein means an average width of a wiring portion of the conductive film 7, which is provided on a surface of the passivation insulating film 6 and through which the drain current of the thin film transistor is acquired.

The lower limit of an average thickness of the conductive film 7 is preferably 50 nm, and more preferably 80 nm. Meanwhile, the upper limit of the average thickness of the conductive film 7 is preferably 200 nm, and more preferably 150 nm. In a case in which the average thickness of the conductive film 7 is less than the lower limit, the wiring formed of the conductive film 7 may have a high resistance, which may increase the power consumption or a voltage drop at the wiring formed of the conductive film 7. Conversely, in a case in which the average thickness of the conductive film 7 is greater than the upper limit, the average thickness of the conductive film 7 with respect to an average wiring width of the wiring formed of the conductive film 7 may become so large that the wiring becomes susceptible to inclining, which may make disconnection of the wiring itself or a short circuit to a wiring adjacent thereto likely to occur. “Average thickness of the conductive film” as referred to herein means an average thickness of the wiring portion of the conductive film 7, which is provided on the surface of the passivation insulating film 6 and through which the drain current of the thin film transistor is acquired.

Characteristics of Thin Film Transistor

The lower limit of the carrier mobility (electron mobility) of the thin film transistor is preferably 20 cm²/Vs, more preferably 23 cm²/Vs, and still more preferably 30 cm²/Vs. In a case in which the carrier mobility of the thin film transistor is less than the lower limit, the switching characteristics of the thin film transistor may be degraded. Meanwhile, the upper limit of the carrier mobility of the thin film transistor is not particularly limited; in general, the carrier mobility of the thin film transistor is less than or equal to 100 cm²/Vs.

The lower limit of the threshold voltage of the thin film transistor is preferably −1 V, and more preferably 0 V. Meanwhile, the upper limit of the threshold voltage of the thin film transistor is preferably 3 V, and more preferably 2 V. In a case in which the threshold voltage of the thin film transistor is less than the lower limit, leakage current of the switching element in an off state in which no voltage is applied to the gate electrode 1 may increase, which may result in standby power of the thin film transistor being too high. Conversely, in a case in which the threshold voltage of the thin film transistor is greater than the upper limit, the switching element may lack drain current in an on state in which a voltage has been applied to the gate electrode 1.

The upper limit of the threshold voltage shift due to irradiation of the thin film transistor with light is preferably 2 V, more preferably 1.5 V, and still more preferably 1 V. In a case in which the threshold voltage shift is greater than the upper limit, performance of the thin film transistor may be unstable when the thin film transistor is used for a display device, and necessary switching characteristics may fail to be obtained. The lower limit of the threshold voltage shift is preferably 0 V; that is to say, it is preferred that the threshold voltage shift does not occur.

The upper limit of a subthreshold swing value (S value) of the thin film transistor is preferably 0.7 V, and more preferably 0.5 V. In a case in which the S value of the thin film transistor is greater than the upper limit, switching of the thin film transistor may take considerable time. Meanwhile, the lower limit of the S value of the thin film transistor is not particularly limited; in general, the S value of the thin film transistor is greater than or equal to 0.2 V. The “S value” of the thin film transistor as referred to herein means a minimum value of an amount of change in gate voltage needed to increase the drain current by an order of magnitude.

### Production Method of Thin Film Transistor

The thin film transistor can be produced by a production method including, for example, depositing a gate electrode (gate electrode-depositing step), depositing a gate insulating film (gate insulating film-depositing step), depositing an oxide semiconductor thin film (oxide semiconductor thin film-depositing step), depositing an ESL protective film (ESL protective film-depositing step), depositing source and drain electrodes (source and drain electrode-depositing step), depositing a passivation insulating film (passivation insulating film-depositing step), depositing a conductive film (conductive-film-depositing step), and conducting a post-annealing treatment (post-annealing treatment step).

Gate Electrode-Depositing Step

In the gate electrode-depositing step, the gate electrode 1 is deposited on the surface of the substrate X.

Specifically, first, a conductive film is stacked on the surface of the substrate X to a desired thickness by a known procedure such as, for example, a sputtering procedure. Conditions for stacking the conductive film by the sputtering procedure are not particularly limited, and can be, for example, the following conditions: a substrate temperature is greater than or equal to 20° C. and less than or equal to 50° C., a deposition power density is greater than or equal to 3 W/cm² and less than or equal to 4 W/cm², a pressure is greater than or equal to 0.1 Pa and less than or equal to 0.4 Pa, and a carrier gas is Ar.

Next, the conductive film is patterned to form the gate electrode 1. A patterning procedure is not particularly limited, and for example, a procedure in which wet etching is performed after photolithography can be used. In this case, to improve the coverage with the gate insulating film 2, the etching is preferably performed so that the cross section of the gate electrode 1 is tapered so as to expand toward the substrate X.

Gate Insulating Film-Depositing Step

In the gate insulating film-depositing step, the gate insulating film 2 is deposited on the surface side of the substrate X so as to cover the gate electrode 1.

Specifically, first, an insulating film is stacked on the surface side of the substrate X to a desired thickness by a known procedure which may be exemplified by a variety of CVD procedures. For example, in a case in which a silicon oxide film is stacked by a plasma CVD procedure, deposition can be performed using a gas mixture of N₂O and SiH₄ as a source gas under conditions where the substrate temperature is greater than or equal to 300° C. and less than or equal to 400° C., the deposition power density is greater than or equal to 0.7 W/cm² and less than or equal to 1.3 W/cm², and the pressure is greater than or equal to 100 Pa and less than or equal to 300 Pa.

Oxide Semiconductor Thin Film-Depositing Step

In the oxide semiconductor thin film-depositing step, the oxide semiconductor thin film 3 is deposited on a surface of the gate insulating film 2 and directly over the gate electrode 1. Specifically, an oxide semiconductor layer is stacked over the surface of the substrate X, and then the oxide semiconductor layer is patterned, whereby the oxide semiconductor thin film 3 is formed.

Oxide Semiconductor Layer-Stacking

Specifically, first, the oxide semiconductor layer is stacked over the surface of the substrate X by a sputtering procedure using a known sputtering apparatus, for example. By the sputtering procedure, an oxide semiconductor layer superior in in-plane uniformity of its components and thickness can be easily formed.

A sputtering target used in the sputtering procedure is itself another embodiment of the present invention. In other words, the sputtering target is a sputtering target for use in forming the oxide semiconductor thin film 3 and contains In, Zn, and Fe. As the sputtering target, specifically, an oxide target containing In, Zn, and Fe (IZFO target) can be exemplified.

The lower limit of a number of In atoms with respect to a total number of In atoms, Zn atoms, and Fe atoms in the sputtering target accounts for 20 atm %, preferably 29 atm %, and more preferably 34 atm %. Meanwhile, the upper limit of the number of In atoms accounts for 89 atm %, preferably 81 atm %, more preferably 80 atm %, and still more preferably 60 atm %. Furthermore, the lower limit of a number of Zn atoms with respect to the total number of In atoms, Zn atoms, and Fe atoms accounts for 10 atm %, preferably 18 atm %, and more preferably 39 atm %. Meanwhile, the upper limit of the number of Zn atoms accounts for 79 atm %, preferably 70 atm %, and more preferably 65 atm %. Furthermore, the lower limit of a number of Fe atoms with respect to the total number of In atoms, Zn atoms, and Fe atoms accounts for 0.2 atm %, preferably 0.4 atm %, and more preferably 0.5 atm %. Meanwhile, the upper limit of the number of Fe atoms accounts for 2 atm %, preferably 1.8 atm %, more preferably 1 atm %, and still more preferably 0.9 atm %. By using the sputtering target to deposit the oxide semiconductor thin film 3, the thin film transistor having a high carrier mobility and a high resistance to light stress can be produced at relatively low cost.

The sputtering target preferably has a composition identical to that of a desired oxide semiconductor layer. By making the composition of the sputtering target identical to that of the desired oxide semiconductor layer, deviation in a composition of the oxide semiconductor layer to be formed can be inhibited, making the oxide semiconductor layer having the desired composition easy to obtain.

The sputtering target can be produced by, for example, a powder sintering procedure.

It is to be noted that the sputtering target for stacking the oxide semiconductor layer is not limited to the above-described target containing In, Zn, and Fe, and a plurality of targets having different compositions may be used. In this case, the plurality of the targets are configured to contain In, Zn, and Fe as a whole. Furthermore, each of the targets may contain a plurality of elements from In, Zn, and Fe. The plurality of the targets can also be oxide targets containing one or a plurality of elements from In, Zn, and Fe. The plurality of the targets can also by produced by, for example, the powder sintering procedure. In the case of using the plurality of the targets, a co-sputtering procedure, in which the plurality of the targets are concurrently discharged, can be used as the sputtering procedure.

Conditions for stacking the oxide semiconductor layer by the sputtering procedure are not particularly limited, and can be, for example, the following conditions: the substrate temperature is greater than or equal to 20° C. and less than or equal to 50° C., the deposition power density is greater than or equal to 2 W/cm² and less than or equal to 3 W/cm², the pressure is greater than or equal to 0.1 Pa and less than or equal to 0.3 Pa, and the carrier gas is Ar. Furthermore, as an oxygen source, oxygen is preferably contained in an atmosphere. A content of oxygen in the atmosphere can be greater than or equal to 3% by volume and less than or equal to 5% by volume.

It is to be noted that the procedure for stacking the oxide semiconductor layer is not limited to the sputtering procedure; a chemical deposition procedure such as a coating procedure or the like can also be used.

Patterning

Next, the oxide semiconductor layer is patterned to form the oxide semiconductor thin film 3. A procedure for patterning the oxide semiconductor layer is not particularly limited, and, for example, a procedure in which wet etching is performed after photolithography can be used.

It is to be noted that a pre-annealing treatment may be performed after the patterning to reduce a density of trap levels in the oxide semiconductor thin film 3. Accordingly, in the thin film transistor to be produced, the threshold voltage shift due to irradiation with light can be reduced.

The lower limit of a temperature of the pre-annealing treatment is preferably 300° C., and more preferably 350° C. Meanwhile, the upper limit of the temperature of the pre-annealing treatment is preferably 450° C., and more preferably 400° C. If the temperature of the pre-annealing treatment is less than the lower limit, an effect of improving electrical characteristics of the thin film transistor may be insufficient. Conversely, if the temperature of the pre-annealing treatment is greater than the upper limit, the oxide semiconductor thin film 3 may be damaged by heat.

Conditions pertaining to a pressure and a time period of the pre-annealing treatment are not particularly limited, and for example, the following conditions can be employed: an N₂ atmosphere under atmospheric pressure (greater than or equal to 0.9 atmospheres and less than or equal to 1.1 atmospheres) is used and the time period is greater than or equal to 10 min and less than or equal to 60 min.

ESL Protective Film-Depositing Step

In the ESL protective film-depositing step, the ESL protective film 4 is deposited on a portion of a surface of the oxide semiconductor thin film 3 on which the source and drain electrodes 5 are not to be formed.

Specifically, first, an insulating film is stacked on the surface side of the substrate X to a desired thickness by a known procedure which may be exemplified by a variety of CVD procedures. For example, when a silicon oxide film is stacked by a plasma CVD procedure, deposition can be performed using a gas mixture of N₂O and SiH₄ as a source gas under conditions where the substrate temperature is greater than or equal to 100° C. and less than or equal to 300° C., the deposition power density is greater than or equal to 0.2 W/cm² and less than or equal to 0.5 W/cm², and the pressure is greater than or equal to 100 Pa and less than or equal to 300 Pa.

Source and Drain Electrode-Depositing Step

In the source and drain electrode-depositing step, the source electrode 5a and the drain electrode 5b, which are electrically connected to the oxide semiconductor thin film 3 at the both ends of the channel of the thin film transistor, are deposited.

Specifically, first, a conductive film is stacked over the surface of the substrate X to a desired thickness by a known procedure such as, for example, a sputtering procedure. Conditions for stacking the conductive film by the sputtering procedure are not particularly limited, and can be, for example, the following conditions: the substrate temperature is greater than or equal to 20° C. and less than or equal to 50° C., the deposition power density is greater than or equal to 3 W/cm² and less than or equal to 4 W/cm², the pressure is greater than or equal to 0.1 Pa and less than or equal to 0.4 Pa, and the carrier gas is Ar.

Next, the conductive film is patterned to form the source electrode 5a and the drain electrode 5b. A patterning procedure is not particularly limited, and for example, a procedure in which wet etching is performed after photolithography can be used.

Passivation Insulating Film-Depositing Step

In the passivation insulating film-depositing step, the passivation insulating film 6 covering the thin film transistor is deposited.

Specifically, an insulating film is stacked on the surface side of the substrate X to a desired thickness by a known procedure which may be exemplified by a variety of CVD procedures. For example, when a silicon nitride film is stacked by a plasma CVD procedure, deposition can be performed using a gas mixture of NH₃ and SiH₄ as a source gas under conditions where the substrate temperature is greater than or equal to 100° C. and less than or equal to 200° C., the deposition power density is greater than or equal to 0.2 W/cm² and less than or equal to 0.5 W/cm², and the pressure is greater than or equal to 100 Pa and less than or equal to 300 Pa.

Conductive Film-Depositing Step

In the conductive film-depositing step, the conductive film 7, which is electrically connected to the drain electrode 5b through the contact hole 8, is deposited.

Specifically, first, the contact hole 8 is formed by a procedure in which a contact portion with the drain electrode 5b is patterned by a known procedure such as, for example, photolithography, and then dry etching is performed. Next, the conductive film 7, which is electrically connected to the drain electrode 5b through the contact hole 8, is deposited by a known procedure such as, for example, a sputtering procedure. Conditions for stacking the conductive film 7 by the sputtering procedure are not particularly limited, and can be, for example, the following conditions: the substrate temperature is greater than or equal to 20° C. and less than or equal to 50° C., the deposition power density is greater than or equal to 3 W/cm² and less than or equal to 4 W/cm², the pressure is greater than or equal to 0.1 Pa and less than or equal to 0.4 Pa, and the carrier gas is Ar.

Post-Annealing Treatment Step

The post-annealing treatment step is a step in which a final heat treatment is performed. By the heat treatment, the density of trap levels formed on an interface between the oxide semiconductor thin film 3 and the gate insulating film 2 and an interface between the oxide semiconductor thin film 3 and the ESL protective film 4 can be reduced. Accordingly, the threshold voltage shift of the thin film transistor due to irradiation with light can be reduced.

The lower limit of a temperature of the post-annealing treatment is preferably 200° C., and more preferably 250° C. Meanwhile, the upper limit of the temperature of the post-annealing treatment is preferably 400° C., and more preferably 350° C. If the temperature of the post-annealing treatment is less than the lower limit, the effect of improving the electrical characteristics of the thin film transistor may be insufficient. Conversely, if the temperature of the post-annealing treatment is greater than the upper limit, the thin film transistor may be damaged by heat.

Conditions pertaining to a pressure and a time period of the post-annealing treatment are not particularly limited, and for example, the following conditions can be employed: an atmospheric pressure (greater than or equal to 0.9 atmospheres and less than or equal to 1.1 atmospheres) is used and the time period is greater than or equal to 10 min and less than or equal to 60 min. Furthermore, as an atmosphere in which the post-annealing treatment is to be performed, an air atmosphere is permissible, and an inert gas such as nitrogen is preferred. By performing the post-annealing treatment under the atmosphere of the inert gas in this manner, variation in quality of the thin film transistor due to bonding of a molecule or the like contained in the atmosphere to the thin film transistor during the post-annealing treatment can be inhibited.

### Advantages

Since, with respect to the total number of In atoms, Zn atoms, and Fe atoms, the number of In atoms accounts for greater than or equal to 20 atm % and less than or equal to 89 atm %, the number of Zn atoms accounts for greater than or equal to 10 atm % and less than or equal to 79 atm %, and the number of Fe atoms accounts for greater than or equal to 0.2 atm %, the oxide semiconductor thin film 3 has a high resistance to light stress. Furthermore, since the number of Fe atoms in the oxide semiconductor thin film 3 accounts for less than or equal to 2 atm %, the carrier mobility of the thin film transistor formed using the oxide semiconductor thin film 3 is high. Moreover, since the oxide semiconductor thin film 3 does not need to contain Ga, the production cost can be reduced.

Consequently, the thin film transistor formed using the oxide semiconductor thin film 3 is produced at relatively low production cost and has a high carrier mobility and a high resistance to light stress.

### Other Embodiments

The oxide semiconductor thin film, the thin film transistor, and the sputtering target of the present invention are not limited to the above embodiments.

Although the case in which the bottom-gate transistor is used as the thin film transistor has been described in the above embodiments, the thin film transistor may also be a top-gate transistor.

The case in which the thin film transistor includes the ESL protective film has been described in the above embodiments; however, the ESL protective film is not an essential component. For example, in a case of depositing the source and drain electrodes by mask evaporation and/or lift-off, the oxide semiconductor thin film is less likely to be damaged; therefore, the ESL protective film can be omitted.

Furthermore, the case in which the oxide semiconductor thin film contains substantially no metal element other than In, Zn, and Fe has been described in the above embodiments; however, the oxide semiconductor thin film may contain an other metal element. Examples of the other metal element include Sn and the like.

### EXAMPLES

Hereinafter, the present invention will be described in detail by way of Examples; however, the Examples are not construed as limiting the present invention.

### Example 1

A glass substrate (“Eagle XG”, manufactured by Corning Incorporated; diameter: 6 inches; thickness: 0.7 mm) was prepared; first, a Mo thin film was deposited on a surface of the glass substrate to an average thickness of 100 nm. Deposition conditions were as follows: the substrate temperature was 25° C. (room temperature), the deposition power density was 3.8 W/cm², the pressure was 0.266 Pa, and the carrier gas was Ar. After the Mo thin film was deposited, a gate electrode was formed by patterning.

Next, as a gate insulating film, a silicon oxide film with an average thickness of 250 nm was deposited by a CVD procedure so as to cover the gate electrode. As a source gas, a gas mixture of N₂O and SiH₄ was used. Deposition conditions were as follows: the substrate temperature was 320° C., the deposition power density was 0.96 W/cm², and the pressure was 133 Pa.

Next, an oxide semiconductor layer with an average thickness of 40 nm which contained substantially only In, Zn, and Fe was formed as an oxide semiconductor layer on a surface side of the glass substrate by a sputtering procedure.

As the sputtering procedure, a procedure which has been conventionally established as a procedure for determining an optimal composition ratio was used. Specifically, the oxide semiconductor layer was deposited in such a manner that three targets, namely an In₂O₃ target, a ZnO target, and an In₂O₃ target to which a Fe chip was attached, were arranged at different positions around the glass substrate, and sputtering was performed on the glass substrate, which was stationary. In such a method, since three targets of different constituent elements are arranged at different positions around a glass substrate, the distance from each target varies depending on the position on the glass substrate. The further a position is distanced from a sputtering target, the greater a reduction in the elements supplied from the target. For example, at a position that is close to the ZnO target and far from the In₂O₃ target, more Zn is supplied than In; conversely, at a position that is close to the In₂O₃ target and far from the ZnO target, more In is supplied than Zn. That is to say, an oxide semiconductor layer in which the composition ratio varies depending on the position on the glass substrate can be obtained.

A sputtering apparatus (“CS200”, manufactured by ULVAC, Inc.) was used, and deposition conditions were as follows: the substrate temperature was 25° C. (room temperature), the deposition power density was 2.55 W/cm², the pressure was 0.133 Pa, and the carrier gas was Ar. Furthermore, a content of oxygen in the atmosphere was 4% by volume.

The oxide semiconductor layer thus obtained was patterned by photolithography and wet etching, whereby an oxide semiconductor thin film in which the composition varied depending on the position on the glass substrate was formed. It is to be noted that “ITO-07N,” manufactured by KANTO CHEMICAL CO., INC., was used as a wet etchant.

Here, a pre-annealing treatment was performed to improve a film quality of the oxide semiconductor thin film. It is to be noted that the pre-annealing treatment was performed in an environment of an air atmosphere (atmospheric pressure) at 350° C. for 60 min.

Next, a silicon oxide film was deposited on the surface side of the glass substrate to an average thickness of 100 nm by a CVD procedure. As a source gas, a gas mixture of N₂O and SiH₄ was used. Deposition conditions were as follows: the substrate temperature was 230° C., the deposition power density was 0.32 W/cm², and the pressure was 133 Pa. After the silicon oxide film was deposited, an ESL protective film was formed by patterning.

Next, a Mo thin film was deposited on the surface side of the glass substrate to an average thickness of 200 nm. Deposition conditions were as follows: the substrate temperature was 25° C. (room temperature), the deposition power density was 3.8 W/cm², the pressure was 0.266 Pa, and the carrier gas was Ar. After the Mo thin film was deposited, a source electrode and a drain electrode were formed by patterning.

Next, a passivation insulating film having a two-layer structure of a silicon oxide film (average thickness: 100 nm) and a silicon nitride film (average thickness: 150 nm) was formed on the surface side of the glass substrate by a CVD method. As a source gas for use in forming the silicon oxide film, a gas mixture of N₂O and SiH₄ was used; as a source gas for use in forming the silicon nitride film, a gas mixture of NH₃ and SiH₄ was used. Deposition conditions were as follows: the substrate temperature was 150° C., the deposition power density was 0.32 W/cm², and the pressure was 133 Pa.

Next, a contact hole was formed by photolithography and dry etching, and a pad for electrical connection to the drain electrode was provided. Putting a probe on the pad enabled an electrical measurement on a thin film transistor.

Finally, a post-annealing treatment was performed. It is to be noted that the post-annealing treatment was performed in an environment of an N₂ atmosphere under atmospheric pressure at 250° C. for 30 min

In this manner, a thin film transistor of Example 1 was obtained. It is to be noted that the thin film transistor had a channel length of 20 μm and a channel width of 200 μm. Furthermore, the composition of the oxide semiconductor thin film in the thin film transistor of Example 1 was as shown in Table 1.

### Examples 2 to 15, Comparative Examples 1 to 7

Thin film transistors of Examples 2 to 15 and Comparative Examples 1 to 7 were obtained in a manner similar to that of Example 1 except that the number of In atoms, the number of Zn atoms, and the number of Fe atoms with respect to the total number of In atoms, Zn atoms, and Fe atoms in sputtering targets to be used, i.e., the number of In atoms, the number of Zn atoms, and the number of Fe atoms with respect to the total number of In atoms, Zn atoms, and Fe atoms in oxide semiconductor thin films to be formed; as well as the temperatures of the pre-annealing and the post-annealing were changed as shown in Table 1.

Measurement Method

Measurements of a carrier mobility, a threshold voltage, a threshold voltage shift, and an S value were performed on each of the thin film transistors of Examples 1 to 15 and Comparative Examples 1 to 7.

Of these measurements, the measurements of the carrier mobility, the threshold voltage, and the S value were all calculated from static characteristics (Id-Vg characteristics) of the thin film transistors. The static characteristics were measured using a semiconductor parameter analyzer (“HP4156C,” manufactured by Agilent Technologies, Inc.). The measurement conditions were as follows: a source voltage and a drain voltage were fixed to 0 V and 10 V, respectively, and a gate voltage was changed from −30 V to 30 V by 0.25 V. It is to be noted that the measurements were performed at room temperature (25° C.). Measurement methods are as described below.

Carrier Mobility

The carrier mobility was defined as a field effect mobility μ_{FE} [m²/Vs] in a saturation region of the static characteristics. The field effect mobility μ_{FE} [m²/Vs] was calculated from μ_{FE} [m²/VS] in the saturation region (V_{g}>V_{d}−Vₜₕ) of the static characteristics, which is shown in the following formula (3):

$${μ}_{TE} = \frac{\partial {I}_{d}}{\partial {V}_{g}} ( \frac{L}{{C}_{OX} \times W \times ( {V}_{g} - Vth )} ) , \qquad ( 3 )$$

wherein V_{g} [V] denotes the gate voltage, Vₜₕ [V] denotes the threshold voltage, I_{d} [A] denotes the drain current, L [m] denotes the channel length, W [m] denotes the channel width, and Cₒₓ [F] denotes the capacitance of the gate insulating film. The results are shown in Table 1.

Threshold Voltage

The threshold voltage was defined as a gate voltage at which the drain current of a transistor was 10⁻⁹ A, and a value of the gate voltage was calculated from the static characteristics of the each of the thin film transistors. The results are shown in Table 1.

S Value

For the S value, an amount of change in gate voltage needed to increase the drain current by an order of magnitude was calculated from the static characteristics, and a minimum value was taken. The results are shown in Table 1

Threshold Voltage Shift

The threshold voltage shift was calculated in such a manner that the each of the thin film transistors was irradiated with a white LED (“LXHL-PW01”, manufactured by Koninklijke Philips N.V.) for 2 hrs, wherein the substrate temperature was 60° C. and the source voltage, the drain voltage, and the gate voltage of the thin film transistor were fixed to 0 V, 10 V, and −10 V, respectively, and an absolute value of a difference between the threshold voltages before and after the irradiation was calculated. A smaller value of the threshold voltage shift indicates a higher resistance to light stress. The results are shown in Table 1.

Evaluations

Based on the results of the above-described measurements, a comprehensive evaluation was made according to the following criteria. The results are shown in Table 1.

A: The carrier mobility is greater than or equal to 20 m²/Vs and the threshold voltage shift is less than or equal to 2 V; the thin film transistor is suitable for a next-generation large display or a flexible display.

B: The carrier mobility is greater than or equal to 20 m²/Vs and the threshold voltage shift is greater than 2 V and less than or equal to 4 V; the thin film transistor can be used for a next-generation large display and a flexible display.

C: The carrier mobility is less than 20 m²/Vs or the threshold voltage shift is greater than 4 V; the thin film transistor cannot be used for a next-generation large display or a flexible display.

TABLE 1

| | Annealing | | | | | | | Threshold | | |
|---|---|---|---|---|---|---|---|---|---|---|
| | treatment | | Composition | | | Carrier | Threshold | voltage | | |
| | Pre- | Post- | In | Zn | Fe | mobility | voltage | shift | S value | Comprehensive |
| | (° C.) | (° C.) | (atm %) | (atm %) | (atm %) | (cm²/Vs) | (V) | (V) | (V/dec) | evaluation |
| Example 1 | 350 | 250 | 56.6 | 42.7 | 0.7 | 32.3 | 0.25 | 0.50 | 0.3 | A |
| Example 2 | 350 | 250 | 53.5 | 45.6 | 0.9 | 28.4 | 0.50 | 0.50 | 0.3 | A |
| Example 3 | 350 | 250 | 50.4 | 48.4 | 1.2 | 25.0 | 1.00 | 0.50 | 0.4 | A |
| Example 4 | 350 | 250 | 48.2 | 50.2 | 1.6 | 25.5 | 0.75 | 0.75 | 0.4 | A |
| Example 5 | 400 | 250 | 35.0 | 64.4 | 0.6 | 23.2 | 2.00 | 0.50 | 0.3 | A |
| Example 6 | 400 | 300 | 37.0 | 62.4 | 0.7 | 24.4 | 1.25 | 0.50 | 0.2 | A |
| Example 7 | 350 | 250 | 49.1 | 49.0 | 1.9 | 20.6 | 1.50 | 0.50 | 0.5 | A |
| Example 8 | 400 | 300 | 79.6 | 18.8 | 1.6 | 48.0 | 0.25 | 0.50 | 0.2 | A |
| Example 9 | 350 | 280 | 41.7 | 57.6 | 0.8 | 23.1 | 1.75 | 0.25 | 0.3 | A |
| Example 10 | 350 | 280 | 61.4 | 37.5 | 1.2 | 32.6 | 2.25 | 0.50 | 0.4 | A |
| Example 11 | 350 | 280 | 69.6 | 29.0 | 1.4 | 40.1 | 1.50 | 1.25 | 0.5 | A |
| Example 12 | 400 | 300 | 50.0 | 49.6 | 0.4 | 30.8 | 0.75 | 1.00 | 0.2 | A |
| Example 13 | 350 | 250 | 52.0 | 47.8 | 0.2 | 26.3 | 2.00 | 1.00 | 0.4 | A |
| Example 14 | 350 | 300 | 56.5 | 43.2 | 0.3 | 34.2 | 0.25 | 1.00 | 0.5 | A |
| Example 15 | 350 | 250 | 62.1 | 37.5 | 0.4 | 28.6 | 1.00 | 1.25 | 0.4 | A |
| Comparative Example 1 | 400 | 300 | 37.2 | 62.8 | 0.0 | 21.5 | 6.25 | 7.50 | 0.3 | C |
| Comparative Example 2 | 400 | 300 | 60.8 | 39.2 | 0.0 | 34.7 | 6.25 | 7.50 | 0.3 | C |
| Comparative Example 3 | 350 | 250 | 46.6 | 53.4 | 0.0 | 32.2 | 0.00 | 11.25 | 0.3 | C |
| Comparative Example 4 | 350 | 250 | 78.8 | 21.2 | 0.0 | 42.2 | 4.00 | 18.50 | 0.4 | C |
| Comparative Example 5 | 350 | 250 | 51.8 | 45.9 | 2.2 | 19.5 | 1.50 | 0.75 | 0.5 | C |
| Comparative Example 6 | 350 | 250 | 55.3 | 41.7 | 3.0 | 19.7 | 1.25 | 0.75 | 0.7 | C |
| Comparative Example 7 | 400 | 300 | 81.2 | 18.8 | 0.0 | Conductor | — | — | — | C |

In the “Carrier mobility” column in Table 1, “Conductor” means that the thin film transistor turned into a conductor and did not exhibit MOS characteristics. Furthermore, “-” in the “Threshold voltage,” “Threshold voltage shift,” and “S value” columns means that these values were not able to be measured because the thin film transistor had turned into a conductor.

According to Table 1, the thin film transistors of Examples 1 to 15 each showed a high carrier mobility and a small threshold voltage shift. In contrast, the thin film transistors of Comparative Examples 1 to 4 each showed a large threshold voltage shift, which is believed to be because their oxide semiconductor thin films did not contain Fe, and these thin film transistors were poor in resistance to light stress. Furthermore, the thin film transistors of Comparative Examples 5 and 6 each showed a low carrier mobility, which is believed to be because the number of Fe atoms with respect to the total number of In atoms, Zn atoms, and Fe atoms in the oxide semiconductor thin films accounted for greater than 2 atm %, and these thin film transistors were poor in switching operations. Furthermore, the thin film transistor of Comparative Example 7 turned into a conductor, which is believed to be because its oxide semiconductor thin film did not contain Fe and the number of In atoms with respect to the total number of In atoms, Zn atoms, and Fe atoms was large.

The above results indicate that the carrier mobility and the resistance to light stress can be increased by setting, with respect to the total number of In atoms, Zn atoms, and Fe atoms in the oxide semiconductor thin film, the number of In atoms to account for greater than or equal to 20 atm % and less than or equal to 89 atm %, the number of Zn atoms to account for greater than or equal to 10 atm % and less than or equal to 79 atm %, and the number of Fe atoms to account for greater than or equal to 0.2 atm % and less than or equal to 2 atm %.

For all of Examples 1 to 6 and Examples 8 to 15, which include the oxide semiconductor thin films in which with respect to the total number of In atoms, Zn atoms, and Fe atoms, the number of In atoms accounts for greater than or equal to 34 atm % and less than or equal to 80 atm %, the number of Zn atoms accounts for greater than or equal to 18 atm % and less than or equal to 65 atm %, and the number of Fe atoms accounts for greater than or equal to 0.2 atm % and less than or equal to 1.8 atm %, the carrier mobilities are greater than or equal to 23 cm²/Vs. Meanwhile, for Example 7, in which the number of atoms in the oxide semiconductor thin film does not fall within the above-described range of the number of atoms, the carrier mobility is less than 23 cm²/Vs. This indicates that the carrier mobility can be improved by setting the number of In atoms to account for greater than or equal to 34 atm % and less than or equal to 80 atm %, the number of Zn atoms to account for greater than or equal to 18 atm % and less than or equal to 65 atm %, and the number of Fe atoms to account for greater than or equal to 0.2 atm % and less than or equal to 1.8 atm %.

Furthermore, for all of Examples 1, 2, 5, 6, 9, 12, 13, and 14, which include the oxide semiconductor thin films in which the number of In atoms accounts for greater than or equal to 34 atm % and less than or equal to 60 atm %, the number of Zn atoms accounts for greater than or equal to 39 atm % and less than or equal to 65 atm %, and the number of Fe atoms accounts for greater than or equal to 0.2 atm % and less than or equal to 0.9 atm %, the threshold voltage shifts are less than or equal to 1 V. Meanwhile, of Examples in which the number of atoms in the oxide semiconductor thin films does not fall within the above described range of the number of atoms, there are instances (Examples 11 and 15) in which the threshold voltage shifts are 1.25 V. This indicates that the resistance to light stress can be improved and performance stability of the thin film transistor can be increased by setting the number of In atoms to account for greater than or equal to 34 atm % and less than or equal to 60 atm %, the number of Zn atoms to account for greater than or equal to 39 atm % and less than or equal to 65 atm %, and the number of Fe atoms to account for greater than or equal to 0.2 atm % and less than or equal to 0.9 atm %.

### INDUSTRIAL APPLICABILITY

As described above, a thin film transistor formed using the oxide semiconductor thin film is produced at relatively low cost and has a high carrier mobility and a high resistance to light stress. Accordingly, the thin film transistor can be suitably used for, for example, a next-generation large display, which is required to have high-speed performance. Furthermore, by use of the sputtering target, an oxide semiconductor thin film having a high carrier mobility and a high resistance to light stress can be formed at relatively low cost.

### EXPLANATION OF THE REFERENCE SYMBOLS

1 Gate electrode
2 Gate insulating film
3 Oxide semiconductor thin film
4 ESL protective film
5 Source and drain electrodes
5a Source electrode
5b Drain electrode
6 Passivation insulating film
7 Conductive film
8 Contact hole
X Substrate

1. An oxide semiconductor thin film comprising In, Zn, and Fe, wherein,
with respect to a total number of In atoms, Zn atoms, and Fe atoms,
a number of In atoms accounts for greater than or equal to 20 atm % and less than or equal to 89 atm %,
a number of Zn atoms accounts for greater than or equal to 10 atm % and less than or equal to 79 atm %, and
a number of Fe atoms accounts for greater than or equal to 0.2 atm % and less than or equal to 2 atm %.

2. The oxide semiconductor thin film according to claim 1, wherein,
with respect to the total number of In atoms, Zn atoms, and Fe atoms,
the number of In atoms accounts for greater than or equal to 34 atm % and less than or equal to 80 atm %,
the number of Zn atoms accounts for greater than or equal to 18 atm % and less than or equal to 65 atm %, and
the number of Fe atoms accounts for greater than or equal to 0.2 atm % and less than or equal to 1.8 atm %.

3. The oxide semiconductor thin film according to claim 1, wherein,
with respect to the total number of In atoms, Zn atoms, and Fe atoms,
the number of In atoms accounts for greater than or equal to 34 atm % and less than or equal to 60 atm %,
the number of Zn atoms accounts for greater than or equal to 39 atm % and less than or equal to 65 atm %, and
the number of Fe atoms accounts for greater than or equal to 0.2 atm % and less than or equal to 0.9 atm %.

4. A thin film transistor comprising the oxide semiconductor thin film according to claim 1.

5. The thin film transistor according to claim 4, wherein a threshold voltage shift due to irradiation with light is less than or equal to 2 V.

6. The thin film transistor according to claim 4, wherein a carrier mobility is greater than or equal to 20 cm²/Vs.

7. The thin film transistor according to claim 5, wherein a carrier mobility is greater than or equal to 20 cm²/Vs.

8. A sputtering target for use in forming an oxide semiconductor thin film, the sputtering target comprising In, Zn, and Fe, wherein,
with respect to a total number of In atoms, Zn atoms, and Fe atoms,
a number of In atoms accounts for greater than or equal to 20 atm % and less than or equal to 89 atm %,
a number of Zn atoms accounts for greater than or equal to 10 atm % and less than or equal to 79 atm %, and
a number of Fe atoms accounts for greater than or equal to 0.2 atm % and less than or equal to 2 atm %.
